(19) United States
(12) Patent Application Publication
(10) Pub. No.: US 2015/0049435 A1
(43) Pub. Date: Feb. 19, 2015

(54) ELECTRONIC DEVICE

(71) Applicants: HONG FU JIN PRECISION INDUSTRY (ShenZhen) CO., LTD., Shenzhen (CN); HON HAI PRECISION INDUSTRY CO., LTD., New Taipei (TW)

(72) Inventors: LI-FANG FAN, Shenzhen (CN); CHAO-KE WEI, New Taipei (TW)

(21) Appl. No.: 14/460,100

(22) Filed: Aug. 14, 2014

(30) Foreign Application Priority Data
Aug. 16, 2013 (CN) 2013103573833

(51) Int. Cl. H05K 7/20

(52) U.S. Cl. CPC H05K 7/20145; H05K 2007/20027
USPC 361/695

(57) ABSTRACT

An electronic device includes a chassis, a power supply, and an air duct. The chassis includes a top plate, two side plates, a front plate set in a front of the top plate, and a baffle set at an inside of the front plate. The front plate, the baffle, the top plate and the side plates together define a receiving cavity for receiving the power supply. The front plate includes an air inlet adjacent to one end of the power supply. A fan is set at another end of the power supply. The side plate defines an opening. The air duct set on an outside of the side plate with the opening. An air channel is formed between the air duct and the side plate with the opening. A distal end of the channel forms an air outlet.

### FIELD

The subject matter herein generally relates to an electronic device.

### BACKGROUND

In electronic devices, such as a server or a computer, electronic components, such as hard disks, are installed, arranged in rows. Usually air cooling is used in the electronic devices via air inlets to cool the electronic components.

### BRIEF DESCRIPTION OF THE DRAWINGS

Implementations of the present technology will now be described, by way of example only, with reference to the attached figures.

FIG. 1 is an isometric view of an embodiment of an electronic device.

FIG. 2 is a partially exploded, isometric view of FIG. 1.

FIG. 3 is a partially exploded, isometric view of FIG. 1, but viewed from another angle.

FIG. 4 is a schematic view showing an airflow path of the electronic device in FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiment described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series and the like.

The present disclosure is described in relation to an electronic device.

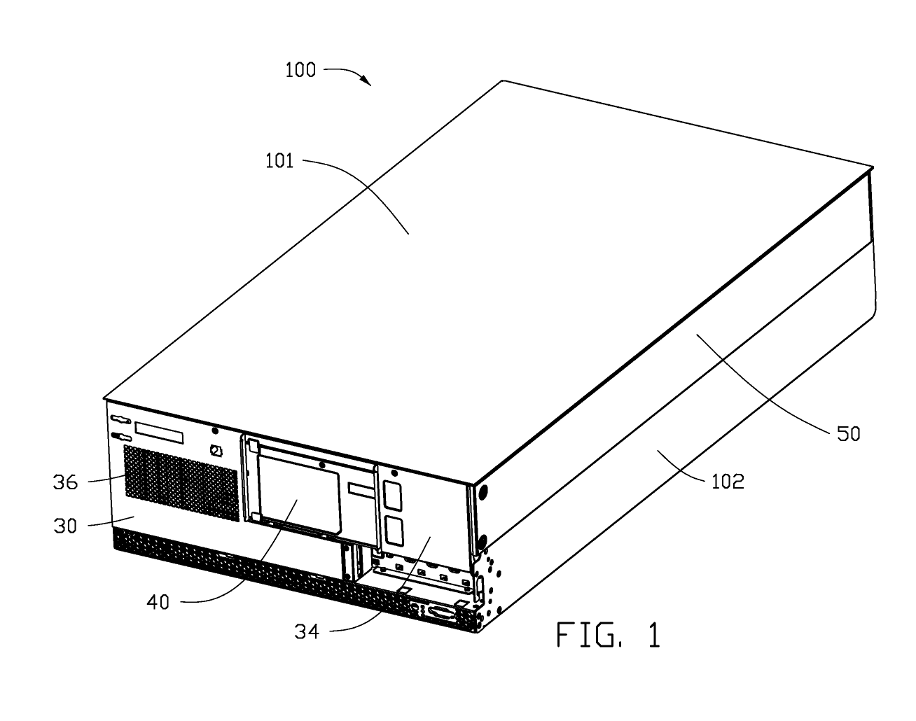

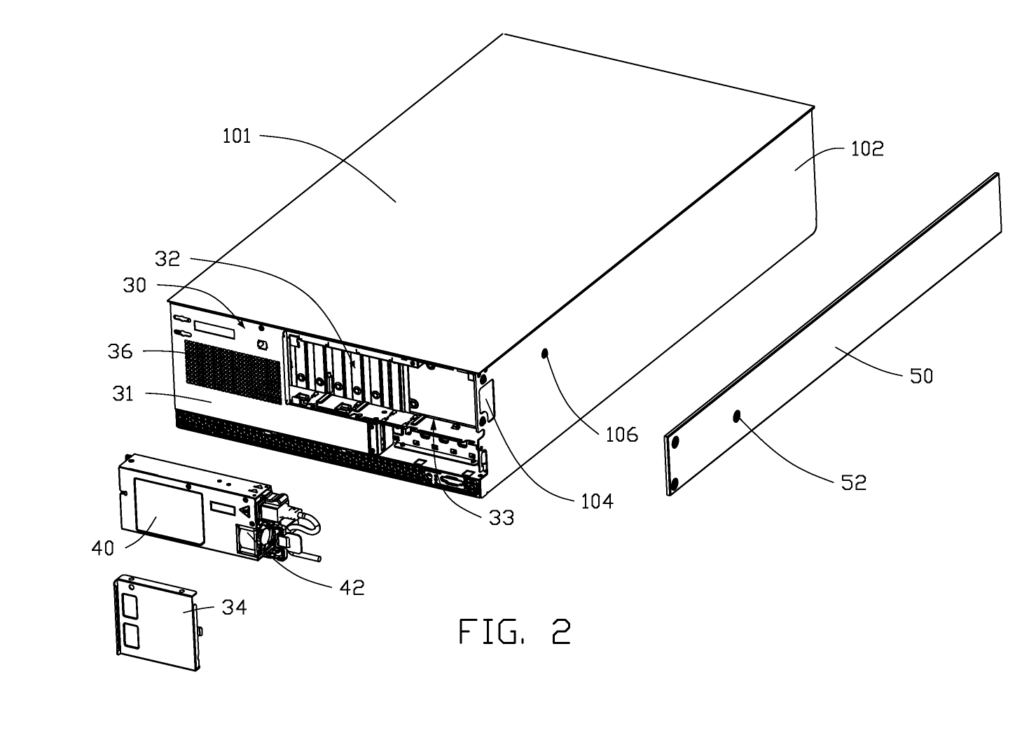

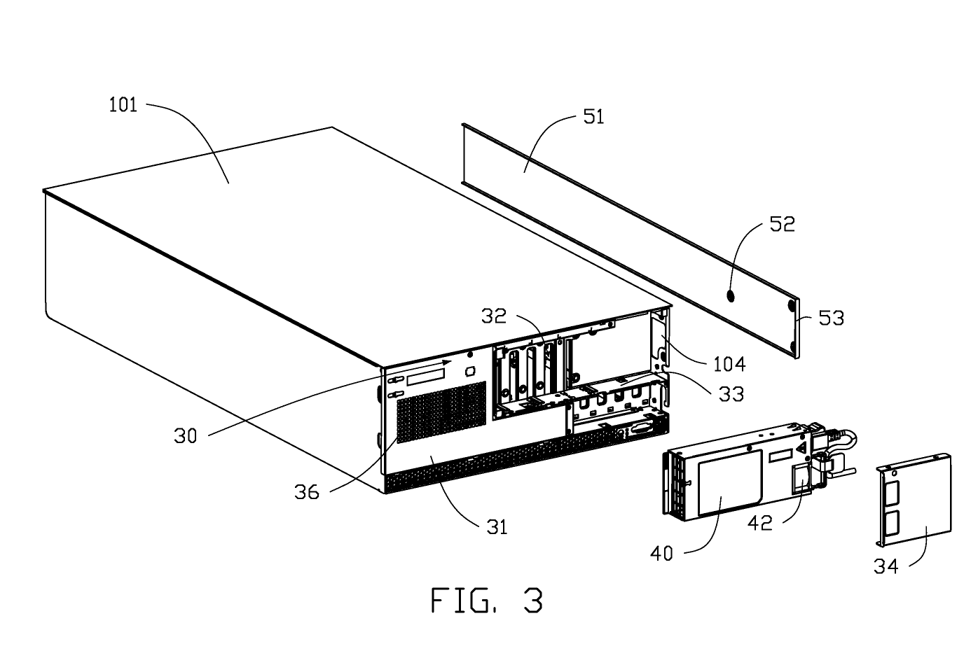

FIGS. 1-3 illustrate an embodiment of an electronic device includes a chassis 100, a power supply 40 and a deflector 50 installed at a side of the chassis 100. The chassis 100 includes a front plate 30, a top plate 101 and two side plates 102. The chassis 100 includes a baffle 32 attached at an inside of and parallel to the front plate. A supporting plate 33 connects between the baffle 32 and the front plate 30, which is parallel to the top plate 101. The front plate 30, the baffle 32, the supporting plate 33, the top plate 101 and the two side plates 102 together define a receiving cavity 110 for receiving the power supply 40. The front plate 30 includes an L-shaped covering plate 31 and a closing plate 34. The L-shaped covering plate 31 defines a cutout at the corner and the power supply 40 is installed in the receiving cavity 110 through the cutout. The closing plate 34 is detachably attached to the covering plate 31. A fan 42 is located at an end of the power supply 40 adjacent to the closing plate 34. The covering plate 31 defines an air inlet 36 above the supporting plate 33 and adjacent to one end of the power supply 40. The baffle 32 is used to insulate the other electronic elements in the electronic device such as hard disk drives, expansion cards and so on.

The right side plate 102 of the chassis 100 defines an opening 104 communicating to the receiving cavity 110, and a plurality of screw holes 106. The deflector 50 is installed on the outside of the side plate 102. The deflector 50 includes a rectangular main plate 51 and a U-shaped flange 53 extending from the top edge, the bottom edge and the front edge of the main plate 51. The main plate 51 includes a plurality of studs 52 extending from the inside wall, corresponding to the screw holes 106. The screws extend through the studs 52 and screw in the screw holes 106, to fix the deflector 50 to the side plate 102. The flange 53 abuts to the surface of the main plate 102 to form an air flow channel 120 between the main plate 51 and the side plate 102 with the opening 104. An air outlet 54 is formed between an end of the deflector 50 away from the covering plate 34 and the side plate 102.

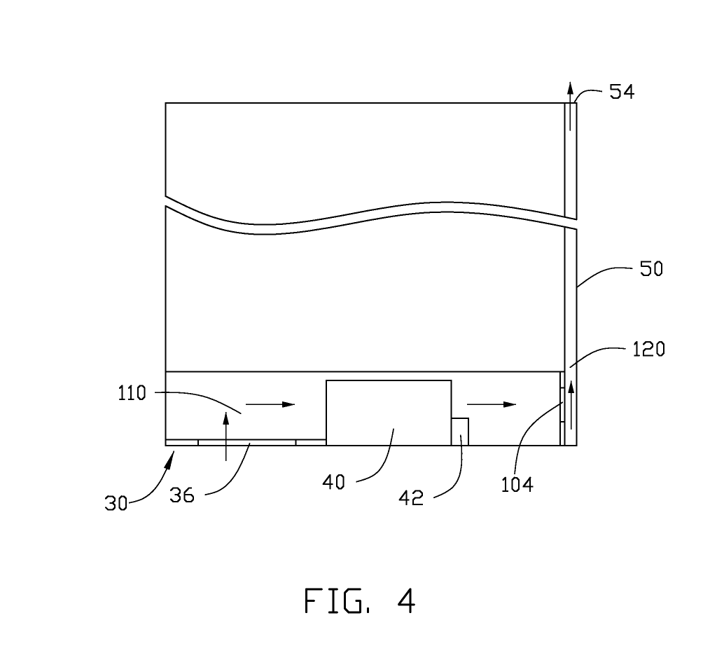

FIG. 4 illustrates when the power supply 40 supplies power to the electronic device, the fan 40 operates, and cool air flows through the air inlet 36, the receiving cavity 110, the power supply 40, the opening 104, the channel 120, and the air outlet 54.

The electronic device includes an individual air flow channel for cooling the power supply 40 and does not affect heat dissipation of other electronic components of the electronic device.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. An electronic device comprising:
a chassis comprising:
a top plate;
two side plates extending from both sides of the top plate;
a front plate set in a front of the top plate; and
a baffle set at an inside of the front plate, wherein the front plate, the baffle, the top plate and the side plates together define a receiving cavity;
a power supply configured to be received in the cavity;
a fan arranged at one end of the power supply; and
a deflector set on an outside of said one of the side plates;
wherein the front plate comprises an air inlet adjacent to the power supply, one of the side plates defines an opening, the deflector and the side plate form an air channel therebetween, the channel has a distal end forming an air outlet; and
wherein when the fan operates, the air flows through the inlet to the receiving cavity to the power supply to the opening to the channel and exits the air outlet.

2. The electronic device of claim 1, wherein the deflector comprises a rectangular main plate, a flange extends from a top edge, a bottom edge and a front edge of the main plate, and the mounting plate is connected to said one of the side plates.

3. The electronic device of claim 1, wherein the chassis further comprises a supporting plate connects between the baffle and the front plate, the supporting plate is parallel to the top plate to support the power supply.

4. The electronic device of claim 1, wherein the front plate comprises a covering plate and a closing plate detachably attached to the covering plate, the covering plate forms a cutout at a corner and the power supply is installed in the receiving cavity through the slot.
